(19) United States
(12) Patent Application Publication
(10) Pub. No.: US 2024/0404896 A1
(43) Pub. Date: Dec. 5, 2024

(54) PATCH INTERPOSER MOLD DESIGN FOR LIQUID METAL CARRIER ARRAY

(71) Applicant: Intel Corporation, Santa Clara, CA (US)

(72) Inventors: Eric ERIKE, Mesa, AZ (US); Srikant NEKKANTY, Chandler, AZ (US); Karumbu MEYYAPPAN, Portland, OR (US); Anikki GIESSLER, Tempe, AZ (US)

(21) Appl. No.: 18/204,212

(22) Filed: May 31, 2023

(51) Int. Cl. H01L 23/13; H01L 21/48; H01L 23/498

(52) U.S. Cl. CPC H01L 23/13; H01L 21/481; H01L 23/49833; H01L 23/49866; H01L 23/538; H01L 24/16; H01L 2224/16225

(57) ABSTRACT

Embodiments described herein include a liquid metal carrier. In an embodiment, the liquid metal carrier includes a substrate that is a polymer. In an embodiment, a first opening is provided through the substrate with a first shape, and a second opening is provided through the substrate with a second shape. In an embodiment, the first shape is different than the second shape.

### TECHNICAL FIELD

Embodiments of the present disclosure relate to electronic systems, and more particularly, to liquid metal carriers that are formed with an injection molding process.

### BACKGROUND

As electronic packages continue to scale and the number of interconnects increases, traditional socketing architectures are reaching their feasible limits. In the case of a land grid array (LGA) socket architecture, the force needed to connect the pins to the package is quickly exceeding assembly capabilities. Accordingly, alternative socketing architectures are needed. One potential solution includes the use of liquid metal. In such architectures, a liquid metal carrier array that includes a plurality of wells is attached to the bottom side of the package substrate. The wells are filled with a liquid metal, such as a material composition comprising gallium. In some instances a capping layer is provided over the wells to confine the liquid metal to the wells. Pins from the board are then inserted through the capping layer in order to make direct contact with the liquid metal.

Liquid metal architectures are promising, but existing solutions are still subject to significant limitations. For example, the wells that are formed in the liquid metal carrier are formed with a drilling process. Tolerances in the drilling process lead to variations in the well diameters. This leads to non-uniform liquid metal volumes, which can negatively impact signal propagation between the board and the package substrate. Drilling processes also result in rough sidewall surfaces, which is not desirable. Further, circular wells are generally the only shape that can be formed with a drilling process. This limits the flexibility in optimizing electrical performance of the liquid metal solution. Physical drilling processes are also limited by a relatively large well diameter. As scaling continues, drilling may not be feasible for fine pitch and small diameter pins.

In addition to limitations in design flexibility, currently available liquid metal solutions are extremely high cost solutions. This is because each well needs to be individually drilled. Small form factors with a limited number of wells may be feasible. However, as scaling and pin count continue to increase (e.g., 1,000 or more pins, 4,000 or more pins, etc.), drilling each well becomes a show stopper.

### BRIEF DESCRIPTION OF THE DRAWINGS

FIG. 1A is a cross-sectional illustration of a liquid metal carrier before formation of the openings.

FIG. 1B is a cross-sectional illustration of the liquid metal carrier during physical drilling of the openings.

FIG. 1C is a plan view illustration of the liquid metal carrier after the openings are drilled.

FIG. 2A is a cross-sectional illustration of a liquid metal carrier that is formed with an injection molding process, in accordance with an embodiment.

FIG. 2B is a plan view illustration of a liquid metal carrier with circular openings, in accordance with an embodiment.

FIG. 2C is a plan view illustration of a liquid metal carrier with polygonal openings, in accordance with an embodiment.

FIG. 2D is a plan view illustration of a liquid metal carrier with a square opening, in accordance with an embodiment.

FIG. 3A is a perspective view of a hole that is a cylindrical shape, in accordance with an embodiment.

FIG. 3B is a perspective view of a hole with a first shape at a top and a second shape at a bottom, in accordance with an embodiment.

FIG. 3C is a perspective view of a hole with an hourglass shape, in accordance with an embodiment.

FIG. 3D is a perspective view of a hole with a tapered shape, in accordance with an embodiment.

FIG. 4A is a cross-sectional illustration of a liquid metal carrier with an opening that includes a side channel, in accordance with an embodiment.

FIG. 4B is a cross-sectional illustration of a liquid metal carrier with a first opening and a second opening that include interdigitated side channels, in accordance with an embodiment.

FIG. 5A is a cross-sectional illustration of a liquid metal carrier with a first opening that is fluidically coupled to a second opening through a channel, in accordance with an embodiment.

FIG. 5B is a plan view illustration of the liquid metal carrier with the first opening fluidically coupled to the second opening through the channel, in accordance with an embodiment.

FIG. 5C is a plan view illustration of a first layer of the liquid metal carrier used to form fluidically coupled openings, in accordance with an embodiment.

FIG. 5D is a cross-sectional illustration of the first layer of the liquid metal carrier used to form fluidically coupled openings, in accordance with an embodiment.

FIG. 5E is a cross-sectional illustration depicting a process for coupling a first layer to a second layer in order to form fluidically coupled openings, in accordance with an embodiment.

FIG. 6 is a plan view illustration of a liquid metal carrier with a plurality of zones that have different opening shapes, in accordance with an embodiment.

FIG. 7 is a plan view illustration of a liquid metal carrier with openings with a first shape surrounded by openings with a second shape, in accordance with an embodiment.

FIGS. 8A-8C are illustrations depicting a process for applying adhesives to a liquid metal carrier, in accordance with an embodiment.

FIGS. 9A and 9B are illustrations depicting a process for applying adhesives to a liquid metal carrier, in accordance with an embodiment.

FIG. 10 is a cross-sectional illustration of an electronic system that includes an injection molded liquid metal carrier, in accordance with an embodiment.

FIG. 11 is a schematic of a computing device built in accordance with an embodiment.

### EMBODIMENTS OF THE PRESENT DISCLOSURE

Described herein are electronic systems, and more particularly, liquid metal carriers that are formed with an injection molding process, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

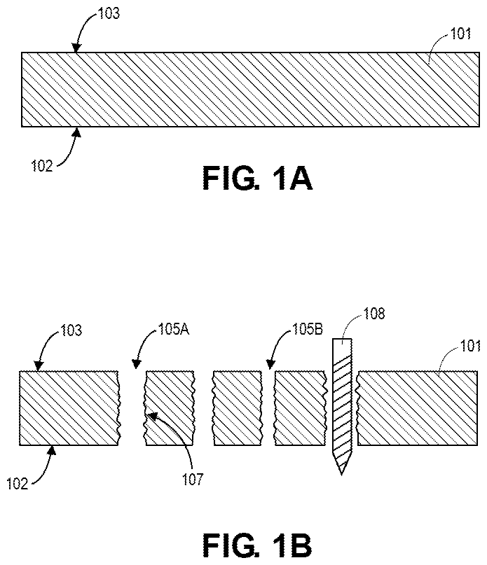

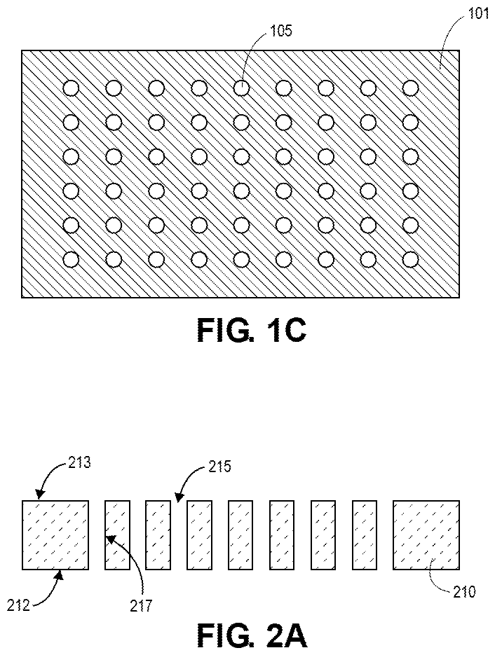

In order to provide context for embodiments disclosed herein, FIGS. 1A-1C are illustrations depicting a traditional liquid metal carrier 101. Referring now to FIG. 1A, a cross-sectional illustration of a liquid metal carrier 101 before the openings are formed is shown. The liquid metal carrier 101 may be an electrically insulating material. More particularly, existing liquid metal carriers 101 need to have a material composition that is compatible with mechanical drilling (e.g., mechanical stress and thermal stress). In one instance, an organic material that is reinforced with fibers, such as glass fibers, may be used. The thickness of the liquid metal carrier 101 may be approximately 100 μm or more. In a particular instance, the thickness of the liquid metal carrier 101 may be between approximately 300 μm and approximately 700 μm. As used herein, “approximately” refers to a range of values within ten percent of the stated value. For example, approximately 100 μm may refer to a range between 90 μm and 110 μm.

Referring now to FIG. 1B, a cross-sectional illustration of the liquid metal carrier 101 during formation of openings 105 is shown. The openings 105 may be formed with a mechanical drilling process. For example, drill 108 passes through the liquid metal carrier 101 to form the openings 105. Due to processing tolerances inherent in mechanical drilling processes, the diameter of the openings may be non-uniform. For example, opening 105A is wider than opening 105B. Variations in opening diameter results in non-uniform liquid metal volumes in each opening. This can lead to issues with electrical performance.

Further, the use of mechanical drilling results in rough sidewall surfaces 107. The sidewall surfaces 107 may have an average roughness Ra that is greater than an average surface roughness Ra of either the top surface 103 or the bottom surface 102. The rough surfaces of the sidewalls 107 may also negatively impact electrical performance of the liquid metal carrier 101.

The use of mechanical drilling is also limited with respect to the shape of the openings 105. Generally, the openings 105 can only be roughly cylindrical shapes. That is, the shape of the openings 105 at the top surface 103 and the bottom surface 102 may be circular, and the sidewalls 107 may be generally vertical. Accordingly, flexibility to modify electrical performance by modifying liquid metal volume is limited.

Referring now to FIG. 1C, a plan view illustration of the completed liquid metal carrier 101 is shown. The liquid metal carrier 101 may comprise an array of openings 105. While shown as being substantially uniform in FIG. 1C, it is to be appreciated that machining tolerances will result in opening 105 diameters being non-uniform, and the placement of the openings 105 may not be perfectly arranged in an ordered array.

The mechanical drilling process may also lead to damage to the liquid metal carrier 101. For example, excess heat provided by the drilling process may negatively impact the structure of the liquid metal carrier 101. Mechanical drilling is also a time consuming process and is expensive. This leads to small form factors for the liquid metal carrier 101. For example, existing mechanical drilling processes may be limited to approximately 35 mm by approximately 50 mm or smaller. As such, existing liquid metal carriers 101 are not compatible with many advanced packaging solutions that require thousands (e.g., 1,000 or more, or 4,000 or more) pins.

Accordingly, embodiments disclosed herein include liquid metal carriers that are formed with an alternative process. More particularly, embodiments include liquid metal carriers that are formed with a molding process, such as an injection molding process. The use of an injection molding process has significant benefits compared to physical drilling. For one, the dimensional control of the openings is improved, which leads to highly uniform liquid metal volumes in each opening. The surface roughness of sidewalls of the openings may also be improved. For example, a surface roughness of the sidewalls of the openings may be substantially equal to the surface roughness of the top and bottom surface of the liquid metal carrier.

Molding processes also enable far greater degrees of design flexibility. For example, the shape of the openings may be circular, square, or any polygonal shape. The shape at the top of the opening may also be different than a shape at the bottom of the opening. Also, openings with different shapes may be formed on a single liquid metal carrier. Molding processes may also allow for sidewalls to be non-vertical. In one instance, the sidewalls may be tapered. In another instance, the sidewalls may have an hourglass shaped profile (i.e., wide at the top and bottom and narrow at the middle).

Molding processes can also be used to form complex opening shapes. For example, an opening may include one or more channels that extend laterally away from the sidewall of the opening. Further, channels may be formed that allow for fluidically coupling together two or more openings. Such embodiments may be enabled through the use of a multi-layered liquid metal carrier.

In addition to design flexibility, molded liquid metal carriers provide improved scaling, while also significantly reducing costs. Since a single molding process is used to form all of the openings substantially in parallel, large form factors (e.g., approximately 150 mm by approximately 150 mm or larger) can be fabricated. The dimensions of the openings are also easier to scale to smaller dimensions. As such, pin counts of approximately 1,000 or more, or approximately 4,000 or more can be cost effectively manufactured. Compared to mechanical drilling processes, injection molding solutions can be one or two (or more) orders of magnitude less expensive.

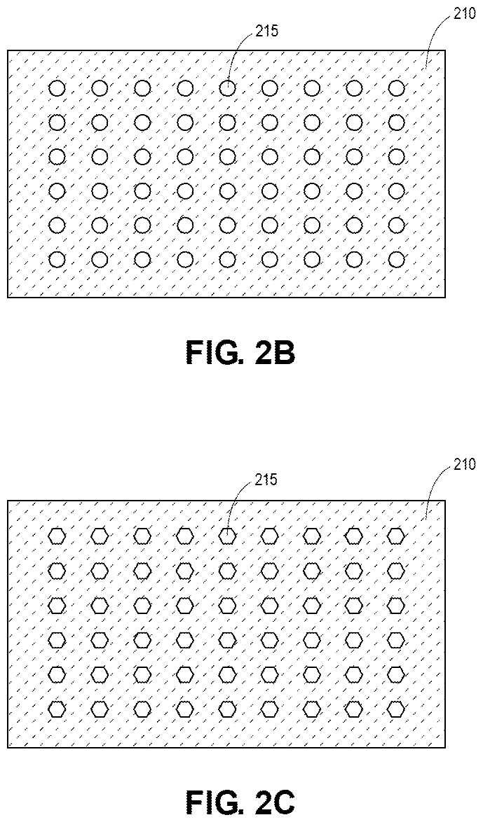

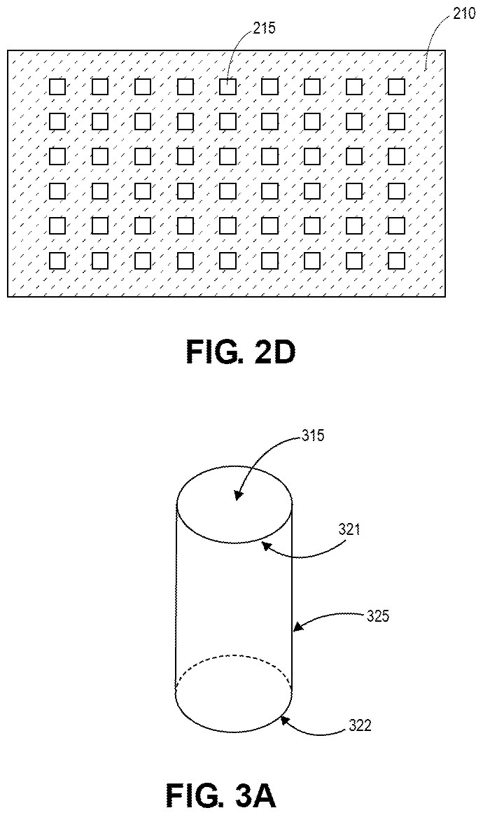

Referring now to FIG. 2A, a cross-sectional illustration of a liquid metal carrier 210 is shown, in accordance with an embodiment. The liquid metal carrier 210 may be formed with a molding process. More particularly, the liquid metal carrier 210 may be formed with an injection molding process. The material composition of the liquid metal carrier 210 may be any suitable polymer that is compatible with injection molding processes. For example, the liquid metal carrier 210 may comprise a polymer, such as, but not limited to, polyvinyl chloride (PVC), polypropylene (PP), polyethylene terephthalate (PET), polymethyl methacrylate (PMMA), high density polyethylene (HDPE), low density polyethylene (LDPE), acrylonitrile butadiene styrene (ABS), styrene acrylonitrile (SAN), or polystyrene.

In an embodiment, the liquid metal carrier 210 may be any suitable thickness. For example, the liquid metal carrier 210 may be approximately 50 μm or thicker, or approximately 100 μm or thicker. In one instance, the liquid metal carrier 210 may have a thickness between approximately 300 μm and approximately 700 μm. In an embodiment, the liquid metal carrier 210 may have any desired form factor. For example, the length and width of the liquid metal carrier 210 may be approximately 150 mm by approximately 150 mm. Though, smaller or larger form factors may also be used in some embodiments.

In an embodiment, a plurality of openings 215 may be provided through a thickness of the liquid metal carrier 210. Injection molding processes allow for a high degree of uniformity between each of the openings 215. For example, in instances where the opening diameter of two openings 215 are intended to be the same, the true difference between the diameter of the two openings 215 may be approximately 1 μm or less, approximately 0.5 μm or less, approximately 0.1 μm or less, or approximately 0.01 μm or less.

In an embodiment, the openings 215 may have substantially vertical sidewalls 217. Though, as will be described in greater detail below, the sidewalls 217 may not be vertical in some embodiments. The injection molding process can result in sidewalls that have a smooth surface. For example, the sidewalls 217 may have an average surface roughness Ra that is substantially equal to the average surface roughness Ra of either the top surface 213 or the bottom surface 212. As used herein, substantially equal average surface roughnesses may refer to surface roughnesses that are within ten percent of each other. In a particular embodiment, the average surface roughness Ra of the sidewalls 217 may be approximately 1 μm or less, approximately 0.1 μm or less, or approximately 0.01 μm or less. In some embodiments, the average surface roughness Ra of the top surface 213 or the bottom surface 212 may refer to an average surface roughness that is measured across a line over the top surface 213 and/or the bottom surface 212. For example, the length of the line may be equal to a length of the top surface 213 and/or the bottom surface 212, the length of the line may be at least approximately 1% of the length of the top surface 213 and/or the bottom surface 212, the length of the line may be at least approximately 10% of the length of the top surface 213 and/or the bottom surface 212, the length of the line may be at least approximately 25% of the length of the top surface 213 and/or the bottom surface 212, or the length of the line may be at least approximately 50% of the length of the top surface 213 and/or the bottom surface 212. In an embodiment, the average surface roughness Ra of the sidewalls 217 may refer to an average surface roughness that is measured across a line along a depth of the sidewall 217. For example, the line may be at least approximately 1% of the depth of the sidewall 217, the line may be at least approximately 10% of the depth of the sidewall 217, the line may be at least approximately 25% of the depth of the sidewall 217, or the line may be at least approximately 50% of the depth of the sidewall 217.

Referring now to FIG. 2B, a plan view illustration of the liquid metal carrier 210 is shown, in accordance with an embodiment. The liquid metal carrier 210 may have an array of openings 215 provided across the surface of the liquid metal carrier 210. While shown as being in a grid array (e.g., a 9×6 grid is shown in FIG. 2B), it is to be appreciated that the openings 215 may be provided with any desired layout. For example, the pitch between each of the openings 215 may be non-uniform in some embodiments.

In an embodiment, the openings 215 are shown as having a circular shape. For example, the openings 215 may have a cylindrical three dimensional shape through the thickness of the liquid metal carrier 210. In the illustrated embodiment, each of the openings 215 have the same diameter. Though, in other embodiments, openings 215 with different diameters may be provided on a single liquid metal carrier 210. In an embodiment, the diameter of the openings 215 may be approximately 50 μm or less, approximately 10 μm or less, or approximately 5 μm or less. Accordingly, aggressive scaling can be enabled using injection molding processes.

Referring now to FIG. 2C, a plan view illustration of a liquid metal carrier 210 is shown, in accordance with yet another embodiment. Instead of being limited to just circular openings 215, it is to be appreciated that non-circular openings may also be used. For example, the openings 215 in FIG. 2C are hexagonal openings. Referring now to FIG. 2D, the openings 215 are square shaped. More generally, the openings 215 may have any polygonal shape, an oval shape, a circular shape, or any irregular shape.

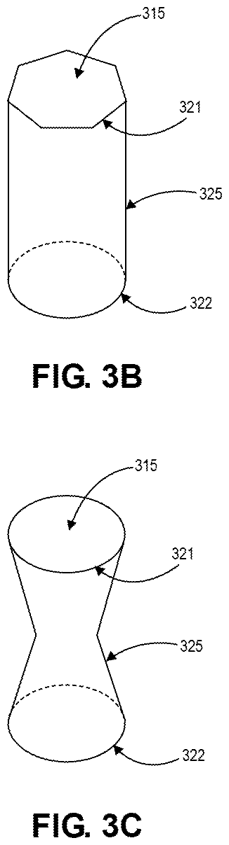

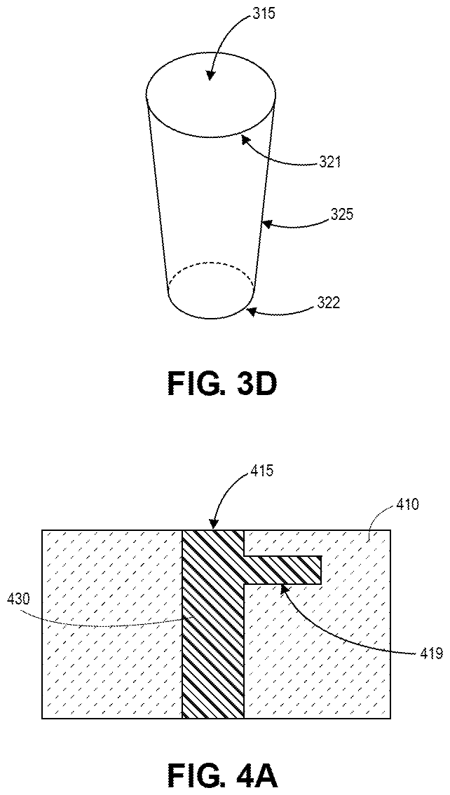

Referring now to FIGS. 3A-3D, examples of various opening 315 shapes are shown, in accordance with various embodiments. In FIGS. 3A-3D, the liquid metal carrier is omitted for clarity. It is to be appreciated that the sidewalls of the openings 315 in FIGS. 3A-3D will be surrounded by an injection molded polymer, such as those described in greater detail above.

Referring now to FIG. 3A, an illustration of an opening 315 is shown, in accordance with an embodiment. The opening 315 may include a first shape 321 at a top surface and a second shape 322 at a bottom surface. The first shape 321 and the second shape 322 may be the same shape and the same size. For example, in FIG. 3A, the first shape 321 and the second shape 322 are both circles with the same diameter. Accordingly, a sidewall 325 of the opening 315 is substantially vertical in order to couple the first shape 321 to the second shape 322. While a circle shape is shown in FIG. 3A, it is to be appreciated that any shape may be used for both the first shape 321 and the second shape 322.

Referring now to FIG. 3B, an illustration of an opening 315 is shown, in accordance with an additional embodiment. The opening 315 may include a first shape 321 at a top surface and a second shape 322 at a bottom surface. In an embodiment, the first shape 321 may be different than the second shape 322. For example, the first shape 321 may be a hexagon, and the second shape 322 may be a circle. The sidewall 325 may be substantially vertical as well. It is to be appreciated that any two shapes may be combined to form the opening 315. For example, a square and a circle may be combined, a square and a hexagon may be combined, or any other suitable shape combination may be used.

Referring now to FIG. 3C, an illustration of an opening 315 is shown, in accordance with an additional embodiment. The opening 315 may include a first shape 321 at a top surface and a second shape 322 at a bottom surface. In an embodiment, the sidewall 325 between the first shape 321 and the second shape 322 may be non-vertical. For example, the sidewall 325 may have a double tapered profile. Such an embodiment may be referred to as being hourglass shaped. An hourglass shape may include a shape that has top and bottom dimensions that are wider than a dimension at a point between the top and bottom surface.

In the illustrated embodiment, the opening 315 has a circular first shape 321 and a circular second shape 322. It is to be appreciated that similar hourglass shapes can be formed with any shapes for the first shape 321 and the second shape 322. In some instances the first shape 321 may be different than the second shape 322, while still having an hourglass shape.

Referring now to FIG. 3D, an illustration of an opening 315 is shown, in accordance with an additional embodiment. The opening 315 may include a first shape 321 at a top surface and a second shape 322 at a bottom surface. In an embodiment, the first shape 321 may be a different size than the second shape 322. For example, the second shape 322 may be smaller than the first shape 321. In such an embodiment, the sidewall 325 may be non-vertical. Such an opening 315 may be referred to as having a tapered shape. While both the first shape 321 and the second shape 322 are shown as circles, it is to be appreciated that a tapered opening 315 may be formed with any shape, or any combination of shapes.

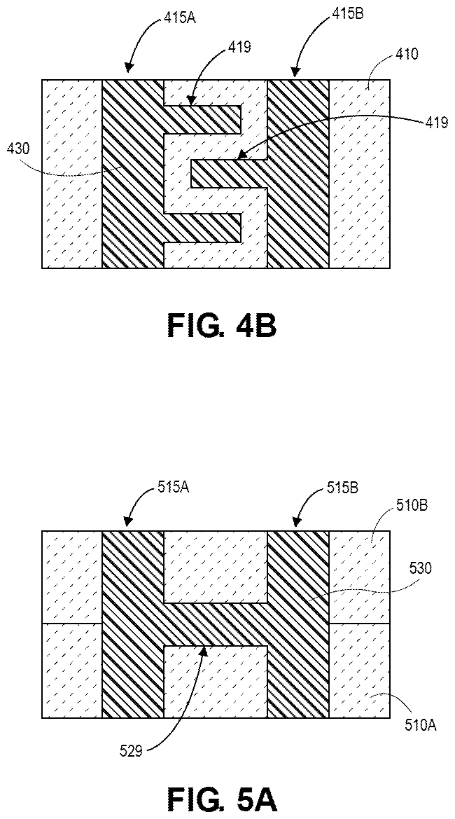

Referring now to FIG. 4A, a cross-sectional illustration of a portion of a liquid metal carrier 410 is shown, in accordance with an embodiment. As shown, the liquid metal carrier 410 may include an opening 415. The opening 415 may be similar to any of the opening architectures described in greater detail above. Additionally, a channel 419 may extend out laterally from the sidewall of the opening 415. Such a lateral channel 419 may be used in order to modulate a volume of liquid metal, provide capacitance tuning capabilities, or provide other electrical signaling improvements.

In the illustrated embodiment, the opening 415 and the channel 419 are filled with a liquid metal 430. As used herein, a liquid metal 430 refers to an electrically conductive material that is in a liquid phase at, or around, room temperature. In some embodiments, the liquid metal 430 may remain in the liquid phase down to around zero degrees Celsius. In a particular embodiment, the liquid metal 430 may comprise gallium with, or without, any other alloying elements. While the previous embodiments are shown without a liquid metal, it is to be appreciated that all liquid metal carries described herein may be at least partially filled with a liquid metal, similar to the liquid metal 430 in FIG. 4A.

Referring now to FIG. 4B, a cross-sectional illustration of a portion of a liquid metal carrier 410 is shown, in accordance with an additional embodiment. In an embodiment, the liquid metal carrier 410 may comprise a first opening 415A that is adjacent to a second opening 415B. The two openings 415A and 415B may be similar to any of the opening architectures described in greater detail herein. In an embodiment, the openings 415A and 415B may each have channels 419 that extend towards the neighboring opening 415A or 415B. In a particular embodiment, the channels 419 are interdigitated with each other. Such an embodiment allows for an increase in the capacitance.

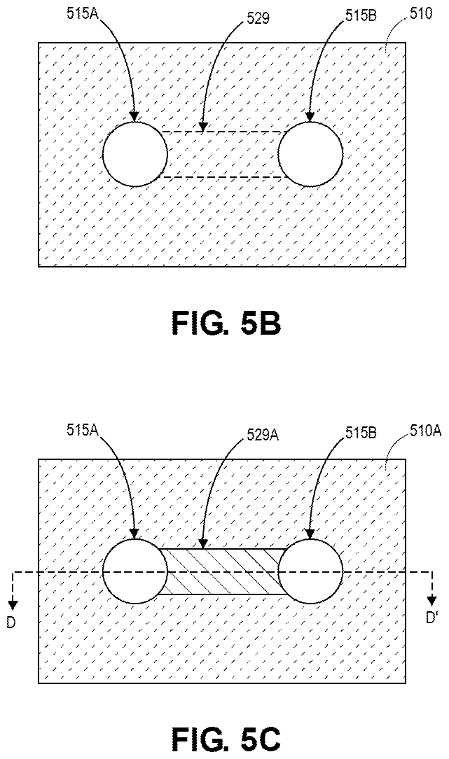

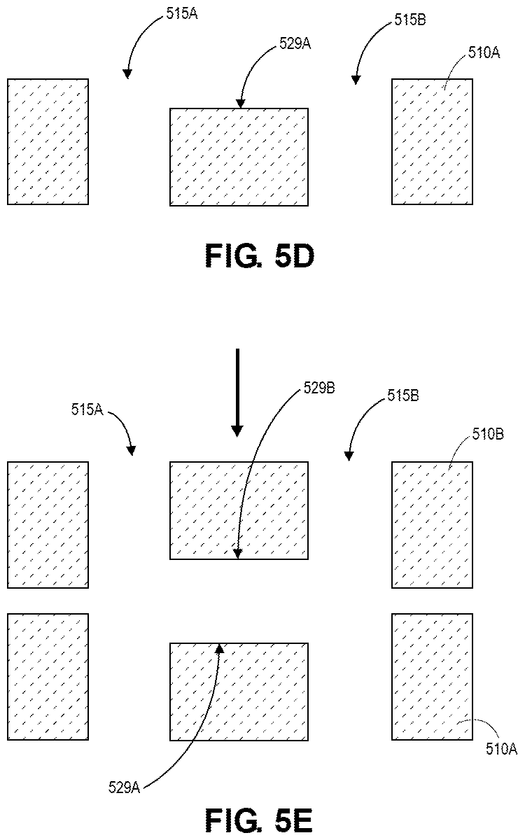

Referring now to FIGS. 5A-5E, a series of illustrations depicting a liquid metal carrier 510 that includes a pair of fluidically coupled openings is shown, in accordance with an embodiment.

Referring now to FIG. 5A, a cross-sectional illustration of a portion of a liquid metal carrier 510 is shown, in accordance with an embodiment. In an embodiment, the liquid metal carrier 510 may comprise a first portion 510A and a second portion 510B over the first portion 510A. The multi-layer approach can be used to enable the structure shown in FIG. 5A, as will be described in greater detail below. In an embodiment, the first portion 510A may be in direct contact with the second portion 510B. In other embodiments, the first portion 510A may be adhered to the second portion 510B by an adhesive layer.

In an embodiment, the liquid metal carrier 510 may include a first opening 515A and a second opening 515B that is adjacent to the first opening 515A. The first opening 515A and the second opening 515B may be similar to any of the opening architectures described in greater detail herein. In an embodiment, a channel 529 is provided between the first opening 515A and the second opening 515B. The channel 529 fluidically couples the first opening 515A to the second opening 515B. For example, liquid metal 530 in the channel 529 may connect the liquid metal 530 in the first opening 515A to the liquid metal 530 in the second opening 515B. Such an embodiment may be useful for applications where multiple pins are to be electrically coupled together. For example, ground pins may be electrically coupled together to provide improved electrical isolation.

Referring now to FIG. 5B, a plan view illustration of the portion of the liquid metal carrier 510 is shown, in accordance with an embodiment. As shown, openings 515A and 515B pass through a thickness of the liquid metal carrier 510. While shown as having circular shapes, it is to be appreciated that openings 515A and 515B may have any shape. As indicated by the dashed lines, the channel 529 is buried within the liquid metal carrier 510.

Referring now to FIG. 5C, a plan view illustration of the first portion 510A of the liquid metal carrier is shown, in accordance with an embodiment. As shown, the first opening 515A and the second opening 515B pass through an entire thickness of the first portion 510A. Additionally, a first portion 529A of the channel 529 is formed between the first opening 515A and the second opening 515B. As indicated by the different shading, the first portion 529A of the channel 529 is a recessed surface from the top of the first portion 510A of the liquid metal carrier 510.

Referring now to FIG. 5D, a cross-sectional illustration of the first portion 510A of the liquid metal carrier 510 along line D-D′ in FIG. 5C is shown, in accordance with an embodiment. As shown, the combined openings (i.e., first opening 515A, second opening 515B, and channel 529A) form a U-shaped structure in the first portion 510A of the liquid metal carrier 510.

Referring now to FIG. 5E, a cross-sectional illustration of the assembly of the liquid metal carrier 510 is shown, in accordance with an embodiment. As shown, the first portion 510A and the second portion 510B may both have U-shaped structures. As indicated by the arrow, the second portion 510B is brought into contact with the first portion 510A. The channel 529A provides one half of the channel 529, and the channel 529B in the second portion 510B provides the other half of the channel 529.

Embodiments that utilize multi-layer constructions allow for the fabrication of more complex structures. For example, some of the structures described above (e.g., in FIGS. 4A and 4B) may also be fabricated using similar multi-layer construction techniques.

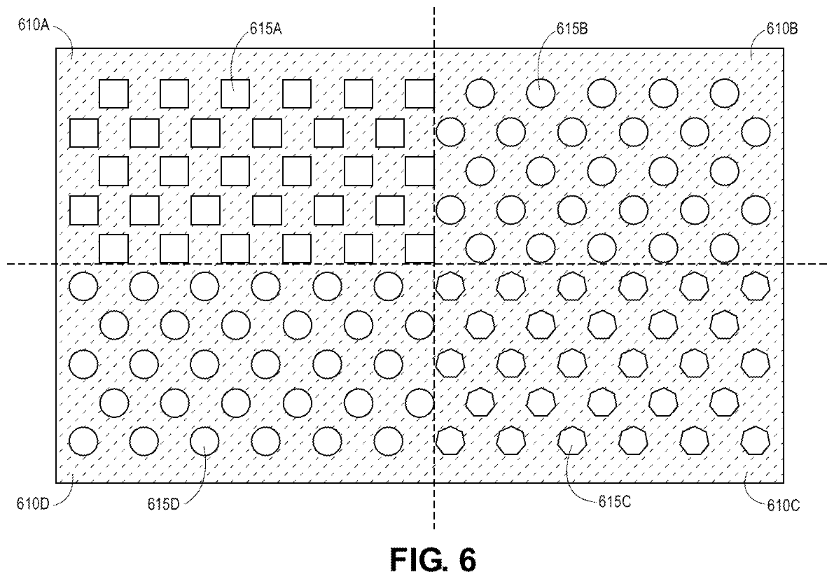

Referring now to FIG. 6, a plan view illustration of a liquid metal carrier 610 is shown, in accordance with an embodiment. As shown, the liquid metal carrier 610 may be divided into a plurality of regions. For example, four regions 610A, 610B, 610C, and 610D are shown in FIG. 6. Each region may require different electrical properties. For example, a first region may be used for HSIO signaling, and a second region may be used for PCIe. Generically, the openings 615A in region 610A are square shaped, the openings 615B in region 610B are circle shaped, the openings 615C in region 610C are heptagon shaped, and the openings 615D in region 610D are circle shaped. While simple opening architectures are shown in FIG. 6, it is to be appreciated that any of the opening architectures described herein may be used. While the regions 610A-610D are provided as quadrants, it is to be appreciated that the regions may take any form.

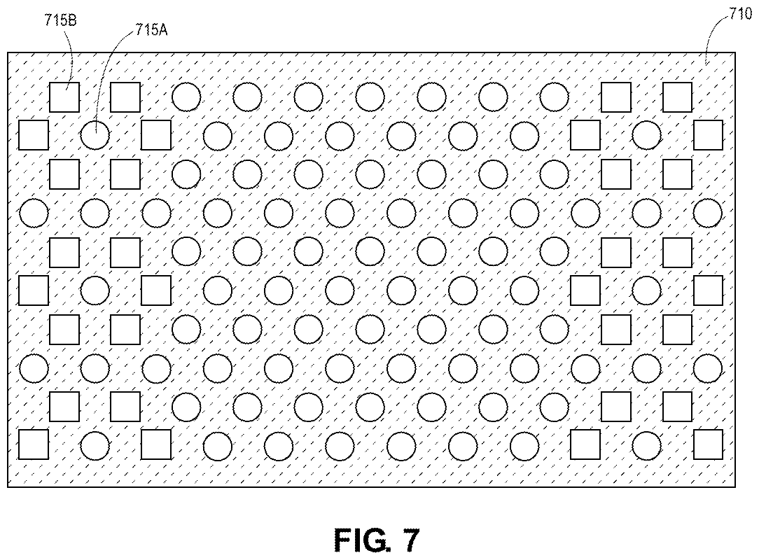

Referring now to FIG. 7, a plan view illustration of a liquid metal carrier 710 is shown, in accordance with yet another embodiment. In the embodiment shown in FIG. 7, first openings 715A with a first shape (e.g., circle) and second openings 715B with a second shape (e.g., square) are provided. The first openings 715A may be adjacent to second openings 715B. More particularly, the second openings 715B may surround individual ones of the first openings 715A. Such an embodiment may be particularly useful when the first opening 715A is for a signaling pin and the second openings 715B are ground pins. While simple opening architectures are shown in FIG. 7, it is to be appreciated that any of the opening architectures described herein may be used. For example, the second openings 715B may be coupled together by channels.

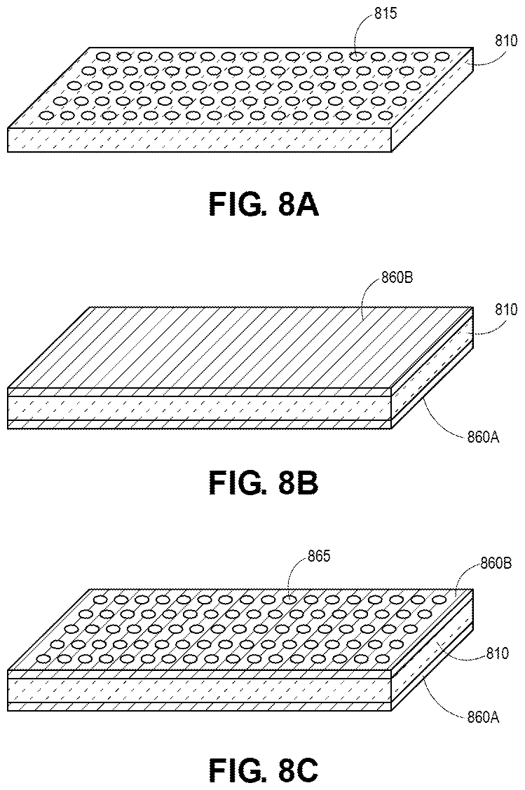

Referring now to FIGS. 8A-8C, a process for preparing a liquid metal carrier 810 for integration into an electronic system is shown, in accordance with an embodiment. The processing shown in FIGS. 8A-8C illustrates how an adhesive can be attached to a top surface and a bottom surface of the liquid metal carrier 810.

Referring now to FIG. 8A, an illustration of a liquid metal carrier 810 is shown, in accordance with an embodiment. The liquid metal carrier 810 may comprise openings 815. The openings 815 may be similar to any of the opening architectures described in greater detail herein. In an embodiment, the liquid metal carrier 810 is formed with an injection molding process.

Referring now to FIG. 8B, an illustration of the liquid metal carrier 810 after a first adhesive 860A and a second adhesive 860B are attached to the liquid metal carrier 810 is shown, in accordance with an embodiment. The adhesives 860A and 860B may be attached with a lamination process.

Referring now to FIG. 8C, an illustration of the liquid metal carrier 810 after openings 865 are formed through the adhesives 860A and 860B is shown, in accordance with an embodiment. In an embodiment, the openings 865 may be formed with a die stamping process or the like. As such, fast throughput is enabled.

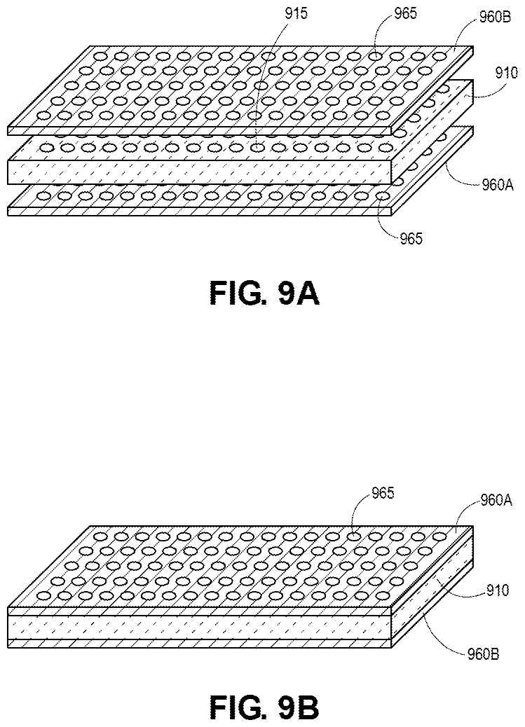

Referring now to FIGS. 9A and 9B, an alternative assembly process is shown, in accordance with an additional embodiment. As shown in FIG. 9A, the liquid metal carrier 910 with openings 915 is provided, and adhesives 960A and 960B with prefabricated openings 965 are aligned with the liquid metal carrier 910. After aligned so that openings 965 are over openings 915, the adhesives 960A and 960B are laminated onto the liquid metal carrier 910, as shown in FIG. 9B.

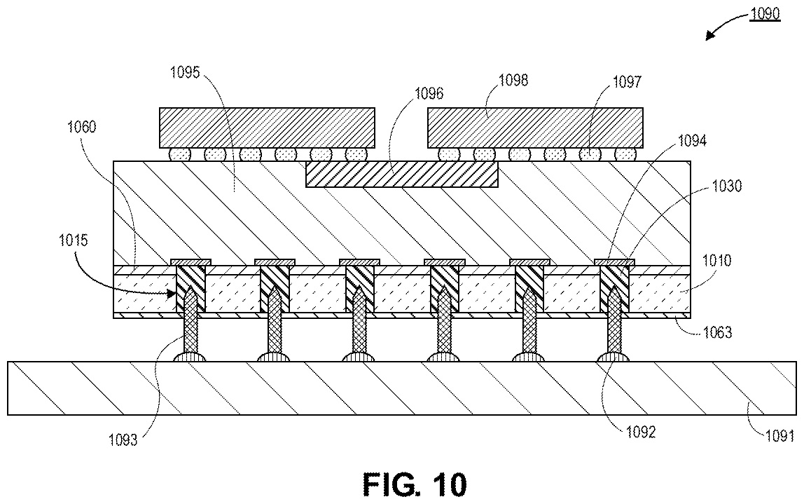

Referring now to FIG. 10, a cross-sectional illustration of an electronic system 1090 is shown, in accordance with an embodiment. In an embodiment, the electronic system 1090 may comprise a board 1091, such as a printed circuit board (PCB). Pins 1093 may be coupled to the board by electrically conductive solder 1092 or other conductive mechanical coupling mechanism.

In an embodiment, a package substrate 1095 may be coupled to the board 1091 using a liquid metal approach. For example, pads 1094 may be directly contacting liquid metal 1030 that is provided in openings 1015 through a liquid metal carrier 1010. The liquid metal carrier 1010 and the openings 1015 may be similar to any liquid metal carrier or opening architecture described in greater detail herein. An adhesive 1060 may secure the liquid metal carrier 1010 to the package substrate 1095. A capping layer 1063 may be provided over the liquid metal carrier 1010 to seal the openings 1015. The pins 1093 may pierce the capping layer 1063, and the pins 1093 directly contact the liquid metal 1030.

In an embodiment, one or more dies 1098 may be coupled to the package substrate 1095 through interconnects 1097, such as a first level interconnect (FLI) architecture. In an embodiment, two or more dies 1098 may be communicatively coupled to each other through a bridge 1096. The bridge 1096 may be embedded in the package substrate 1095 or provided above a surface of the package substrate 1095. In an embodiment, the one or more dies 1098 may be any type of die, such as a central processing unit (CPU), a graphics processing unit (GPU), an XPU, a system on a chip (SoC), a communications die, a memory die, or the like.

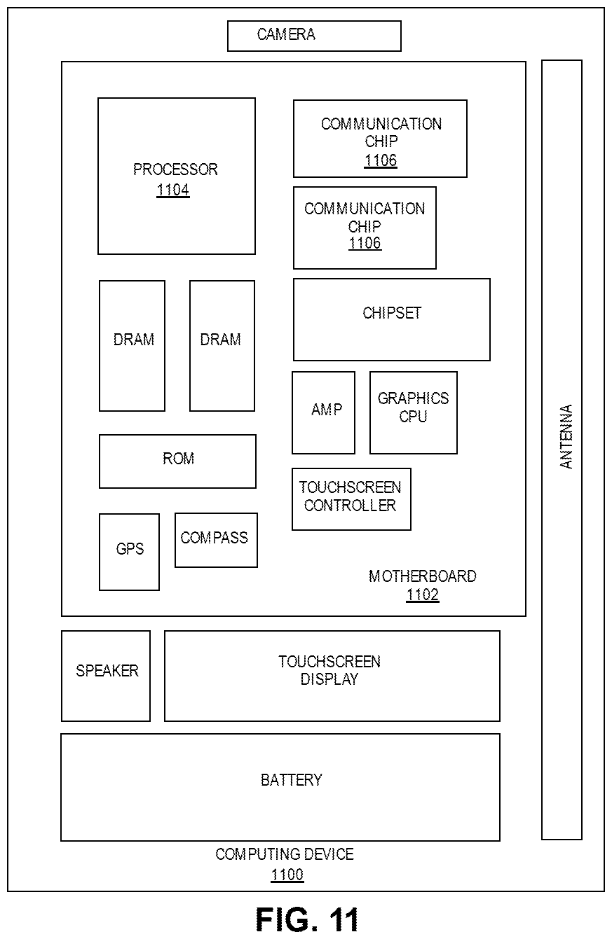

FIG. 11 illustrates a computing device 1100 in accordance with one implementation of the invention. The computing device 1100 houses a board 1102. The board 1102 may include a number of components, including but not limited to a processor 1104 and at least one communication chip 1106. The processor 1104 is physically and electrically coupled to the board 1102. In some implementations the at least one communication chip 1106 is also physically and electrically coupled to the board 1102. In further implementations, the communication chip 1106 is part of the processor 1104.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 1106 enables wireless communications for the transfer of data to and from the computing device 1100. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1106 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 1100 may include a plurality of communication chips 1106. For instance, a first communication chip 1106 may be dedicated to shorter range wireless communications such as Wi-Fi and Bluetooth and a second communication chip 1106 may be dedicated to longer range wireless communications such as GPS, EDGE, GPRS, CDMA, WiMAX, LTE, Ev-DO, and others.

The processor 1104 of the computing device 1100 includes an integrated circuit die packaged within the processor 1104. In some implementations of the invention, the integrated circuit die of the processor may be part of an electronic package that is coupled to a board through an injection molded liquid metal carrier, in accordance with embodiments described herein. The term “processor” may refer to any device or portion of a device that processes electronic data from registers and/or memory to transform that electronic data into other electronic data that may be stored in registers and/or memory.

The communication chip 1106 also includes an integrated circuit die packaged within the communication chip 1106. In accordance with another implementation of the invention, the integrated circuit die of the communication chip may be part of electronic package that is coupled to a board through an injection molded liquid metal carrier, in accordance with embodiments described herein.

In an embodiment, the computing device 1100 may be part of any apparatus. For example, the computing device may be part of a personal computer, a server, a mobile device, a tablet, an automobile, or the like. That is, the computing device 1100 is not limited to being used for any particular type of system, and the computing device 1100 may be included in any apparatus that may benefit from computing functionality.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: a liquid metal carrier, comprising: a substrate, wherein the substrate comprises a polymer; a first opening through the substrate with a first shape; a first conductor in the first opening, wherein the first conductor comprises gallium and one or more alloying elements; a second opening through the substrate with a second shape, wherein the first shape is different than the second shape; and a second conductor in the second opening, wherein the second conductor comprises gallium and one or more alloying elements, and wherein the first conductor is configured for use as a first type of interconnect and the second conductor is configured for use as a second type of interconnect that is different than the first type of interconnect.

Example 2: the liquid metal carrier of Example 1, wherein the first opening is circular, and wherein the second opening is polygonal.

Example 3: the liquid metal carrier of Example 1 or Example 2, wherein the first opening has a top shape at a first surface of the substrate and a bottom shape at a second surface of the substrate, wherein the top shape is different than the bottom shape.

Example 4: the liquid metal carrier of Examples 1-3, wherein one or both of the first shape and the second shape have a non-uniform cross-section through a thickness of the liquid metal carrier.

Example 5: the liquid metal carrier of Example 4, wherein the non-uniform cross-section is a tapered cross-section or an hourglass shaped cross-section.

Example 6: the liquid metal carrier of Examples 1-5, wherein one or both of the first shape and the second shape include one or more side channels.

Example 7: the liquid metal carrier of Examples 1-6, wherein a channel fluidically connects the first opening to the second opening.

Example 8: the liquid metal carrier of Examples 1-7, wherein the first opening is adjacent to the second opening.

Example 9: the liquid metal carrier of Examples 1-8, wherein the polymer comprises polyvinyl chloride (PVC), polypropylene (PP), polyethylene terephthalate (PET), polymethyl methacrylate (PMMA), high density polyethylene (HDPE), low density polyethylene (LDPE), acrylonitrile butadiene styrene (ABS), styrene acrylonitrile (SAN), or polystyrene.

Example 10: a liquid metal carrier, comprising: a substrate with a first surface and a second surface opposite from the first surface, wherein the substrate comprises a polymer, and wherein the first surface and the second surface comprise a first average surface roughness, wherein the first average surface roughness is measured along a line at least partially across a length of the first surface and/or the second surface; an opening through the substrate from the first surface to the second surface, wherein the opening has a sidewall with a second average surface roughness, wherein the second average surface roughness is measured along a line at least partially through a depth of the opening, and wherein the first average surface roughness is substantially equal to the second average surface roughness.

Example 11: the liquid metal carrier of Example 10, wherein the first average surface roughness is approximately 1 μm or less.

Example 12: the liquid metal carrier of Example 10 or Example 11, wherein the first average surface roughness is measured along a line that is at least 10% of the length of the first surface and/or the second surface, and wherein the second average surface roughness is measured along a line that is at least 25% of the depth of the opening.

Example 13: the liquid metal carrier of Examples 10-12, wherein the opening has a cylindrical shape.

Example 14: the liquid metal carrier of Examples 10-13, wherein the opening has a rectangular prism shape.

Example 15: the liquid metal carrier of Examples 10-14, wherein the opening has a first shape at the first surface of the substrate and a second shape at the second surface of the substrate, wherein the first shape is different than the second shape.

Example 16: the liquid metal carrier of Examples 10-15, further comprising a channel that extends out from the sidewall of the opening.

Example 17: an electronic system, comprising: a board, wherein pins extend away from the board; a package substrate coupled to the board, wherein the package substrate comprises: a liquid metal carrier with first openings with first volumes and second openings with second volumes that are different than the first volumes, wherein the first openings and the second openings comprise a liquid metal, wherein the liquid metal carrier comprises a polymer, and wherein the pins directly contact the liquid metal; and a die coupled to the package substrate.

Example 18: the electronic system of Example 17, wherein sidewalls of the openings have a first surface roughness that is substantially equal to a second surface roughness of a top surface or a bottom surface of the liquid metal carrier.

Example 19: the electronic system of Example 17 or Example 18, wherein one or more of the openings have a non-uniform cross-section through a thickness of the opening.

Example 20: the electronic system of Examples 17-19, wherein the electronic system is part of a personal computer, a server, a mobile device, a tablet, or an automobile.

What is claimed is:

1. A liquid metal carrier, comprising:
a substrate, wherein the substrate comprises a polymer;
a first opening through the substrate with a first shape;
a first conductor in the first opening, wherein the first conductor comprises gallium and one or more alloying elements;
a second opening through the substrate with a second shape, wherein the first shape is different than the second shape; and
a second conductor in the second opening, wherein the second conductor comprises gallium and one or more alloying elements, and wherein the first conductor is configured for use as a first type of interconnect and the second conductor is configured for use as a second type of interconnect that is different than the first type of interconnect.

2. The liquid metal carrier of claim 1, wherein the first opening is circular, and wherein the second opening is polygonal.

3. The liquid metal carrier of claim 1, wherein the first opening has a top shape at a first surface of the substrate and a bottom shape at a second surface of the substrate, wherein the top shape is different than the bottom shape.

4. The liquid metal carrier of claim 1, wherein one or both of the first shape and the second shape have a non-uniform cross-section through a thickness of the liquid metal carrier.

5. The liquid metal carrier of claim 4, wherein the non-uniform cross-section is a tapered cross-section or an hourglass shaped cross-section.

6. The liquid metal carrier of claim 1, wherein one or both of the first shape and the second shape include one or more side channels.

7. The liquid metal carrier of claim 1, wherein a channel fluidically connects the first opening to the second opening.

8. The liquid metal carrier of claim 1, wherein the first opening is adjacent to the second opening.

9. The liquid metal carrier of claim 1, wherein the polymer comprises polyvinyl chloride (PVC), polypropylene (PP), polyethylene terephthalate (PET), polymethyl methacrylate (PMMA), high density polyethylene (HDPE), low density polyethylene (LDPE), acrylonitrile butadiene styrene (ABS), styrene acrylonitrile (SAN), or polystyrene.

10. A liquid metal carrier, comprising:
a substrate with a first surface and a second surface opposite from the first surface, wherein the substrate comprises a polymer, and wherein the first surface and the second surface comprise a first average surface roughness, wherein the first average surface roughness is measured along a line at least partially across a length of the first surface and/or the second surface;
an opening through the substrate from the first surface to the second surface, wherein the opening has a sidewall with a second average surface roughness, wherein the second average surface roughness is measured along a line at least partially through a depth of the opening, and wherein the first average surface roughness is substantially equal to the second average surface roughness.

11. The liquid metal carrier of claim 10, wherein the first average surface roughness is approximately 1 μm or less.

12. The liquid metal carrier of claim 10, wherein the first average surface roughness is measured along a line that is at least 10% of the length of the first surface and/or the second surface, and wherein the second average surface roughness is measured along a line that is at least 25% of the depth of the opening.

13. The liquid metal carrier of claim 10, wherein the opening has a cylindrical shape.

14. The liquid metal carrier of claim 10, wherein the opening has a rectangular prism shape.

15. The liquid metal carrier of claim 10, wherein the opening has a first shape at the first surface of the substrate and a second shape at the second surface of the substrate, wherein the first shape is different than the second shape.

16. The liquid metal carrier of claim 10, further comprising a channel that extends out from the sidewall of the opening.

17. An electronic system, comprising:
a board, wherein pins extend away from the board;
a package substrate coupled to the board, wherein the package substrate comprises:
a liquid metal carrier with first openings with first volumes and second openings with second volumes that are different than the first volumes, wherein the first openings and the second openings comprise a liquid metal, wherein the liquid metal carrier comprises a polymer, and wherein the pins directly contact the liquid metal; and
a die coupled to the package substrate.

18. The electronic system of claim 17, wherein sidewalls of the openings have a first surface roughness that is substantially equal to a second surface roughness of a top surface or a bottom surface of the liquid metal carrier.

19. The electronic system of claim 17, wherein one or more of the openings have a non-uniform cross-section through a thickness of the opening.

20. The electronic system of claim 17, wherein the electronic system is part of a personal computer, a server, a mobile device, a tablet, or an automobile.
